(19) United States
(12) Patent Application Publication
(10) Pub. No.: US 2025/0380519 A1
(43) Pub. Date: Dec. 11, 2025

(54) SENSOR PACKAGE STRUCTURE

(71) Applicant: TONG HSING ELECTRONIC INDUSTRIES, LTD., Taoyuan City (TW)

(72) Inventor: LI-CHUN HUNG, Taoyuan City (TW)

(21) Appl. No.: 18/890,105

(22) Filed: Sep. 19, 2024

(30) Foreign Application Priority Data
Jun. 5, 2024 (TW) 113120761

(51) Int. Cl. H01L 27/146; G01S 7/481; H01L 23/00; H01L 23/31; H01L 25/065

(52) U.S. Cl. CPC H10F 39/804; H01L 23/315; H01L 25/0655; H10F 39/8057; G01S 7/4813; H01L 24/48; H01L 2224/48227

(57) ABSTRACT

A sensor package structure includes a substrate, a ring-shaped frame formed on the substrate, two sensor chips disposed on the substrate, a light-permeable layer disposed on the ring-shaped frame, and a light block barrier. The ring-shaped frame defines a chip receiving slot therein. The two sensor chips are located in the chip receiving slot and are electrically coupled to the substrate. The light-permeable layer is disposed on the ring-shaped frame through an inner surface thereof so as to enclose the chip receiving slot and a space surrounded by the chip receiving slot. The top side of the light block barrier is fixed onto the inner surface of the light-permeable layer. The light block barrier is located in the chip receiving slot and is arranged between the two sensor chips.

### CROSS-REFERENCE TO RELATED PATENT APPLICATION

This application claims the benefit of priority to Taiwan Patent Application No. 113120761, filed on Jun. 5, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a package structure, and more particularly to a sensor package structure.

### BACKGROUND OF THE DISCLOSURE

A conventional sensor package structure does not have a structure for separating a plurality of sensor chips from each other, such that when the sensor chips are disposed in the conventional sensor package structure, the sensor chips can easily affect each other and cause misjudgments.

### SUMMARY OF THE DISCLOSURE

In response to the above-referenced technical inadequacies, the present disclosure provides a sensor package structure for effectively improving on the issues associated with conventional sensor package structures.

In order to solve the above-mentioned problems, one of the technical aspects adopted by the present disclosure is to provide a sensor package structure, which includes a substrate, two sensor chips, two ring-shaped supporting layers, a light-permeable layer, a light block barrier, and an encapsulant. The two sensor chips are disposed on and electrically coupled to the substrate. A top surface of each of the two sensor chips includes a sensing region and a carrying region that surrounds the sensing region. The two ring-shaped supporting layers are respectively disposed on the carrying regions of the two sensor chips and respectively surround the sensing regions of the two sensor chips. The light-permeable layer has an inner surface, an outer surface, and a surrounding lateral surface that is connected to the inner surface and the outer surface. The inner surface of the light-permeable layer is disposed on top sides of the two ring-shaped supporting layers, and each of the two ring-shaped supporting layers, the light-permeable layer, and the top surface of a corresponding one of the two sensor chips jointly define an enclosed space. The light block barrier has a top side that is fixed onto the inner surface of the light-permeable layer and that is coplanar with the top sides of the two ring-shaped supporting layers. The light block barrier is arranged between the two sensor chips. The encapsulant is formed on the substrate. The two sensor chips, the two ring-shaped supporting layers, the light block barrier, and the light-permeable layer are embedded in the encapsulant, and the outer surface of the light-permeable layer is at least partially exposed from the encapsulant.

In order to solve the above-mentioned problems, another one of the technical aspects adopted by the present disclosure is to provide a sensor package structure, which includes a substrate, a ring-shaped frame formed on the substrate to jointly define a chip receiving slot, two sensor chips disposed on and electrically coupled to the substrate and arranged in the chip receiving slot, a light-permeable layer and a light block barrier. The light-permeable layer has an inner surface, an outer surface, and a surrounding lateral surface that is connected to the inner surface and the outer surface. The inner surface of the light-permeable layer is disposed on the ring-shaped frame so as to enclose the chip receiving slot and an inner space of the chip receiving slot. The light block barrier has a top side that is fixed onto the inner surface of the light-permeable layer. The light block barrier is arranged in the chip receiving slot and is arranged between the two sensor chips.

Therefore, the light-permeable layer of the sensor package structure in the present disclosure is provided with the light block barrier fixed thereon for separating the two sensor chips from each other, thereby effectively preventing the two sensor chips from affecting each other.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of a sensor package structure according to a first embodiment of the present disclosure;

FIG. 2 is a schematic top view of FIG. 1;

FIG. 3 is a schematic cross-sectional view taken along line III-III of FIG. 2;

FIG. 4 is a schematic cross-sectional view showing the sensor package structure having a gap between a light block barrier and a substrate according to the first embodiment of the present disclosure;

FIG. 5 is a schematic cross-sectional view showing the sensor package structure of FIG. 3 in another configuration;

FIG. 6 is a schematic cross-sectional view showing the sensor package structure of FIG. 3 in yet another configuration;

FIG. 7 is a schematic cross-sectional view of the sensor package structure according to a second embodiment of the present disclosure;

FIG. 8 is a schematic perspective view of a sensor package structure according to a third embodiment of the present disclosure;

FIG. 9 is a schematic cross-sectional view taken along line IX-IX of FIG. 8;

FIG. 10 is a schematic cross-sectional view showing the sensor package structure of FIG. 9 in another configuration; and

FIG. 11 is a schematic cross-sectional view showing the sensor package structure of FIG. 9 in yet another configuration.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

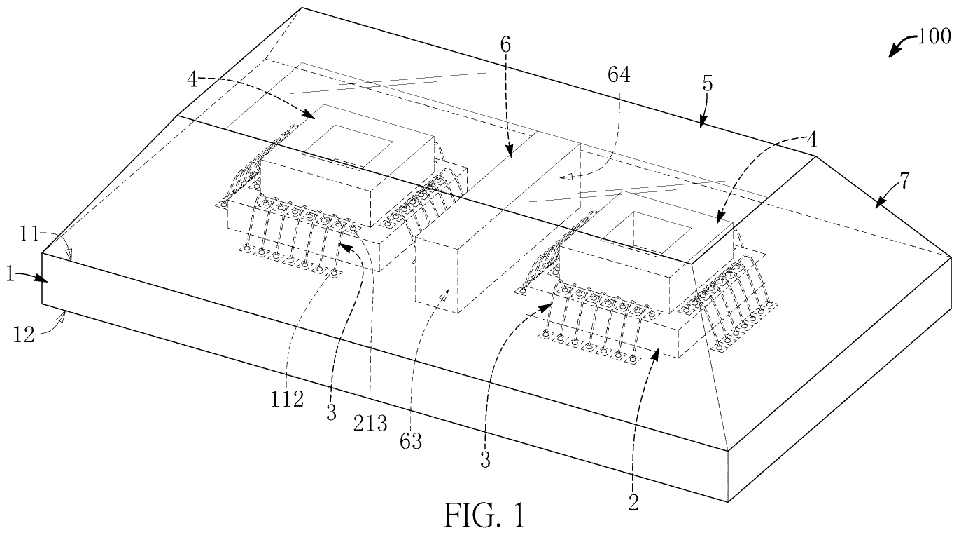

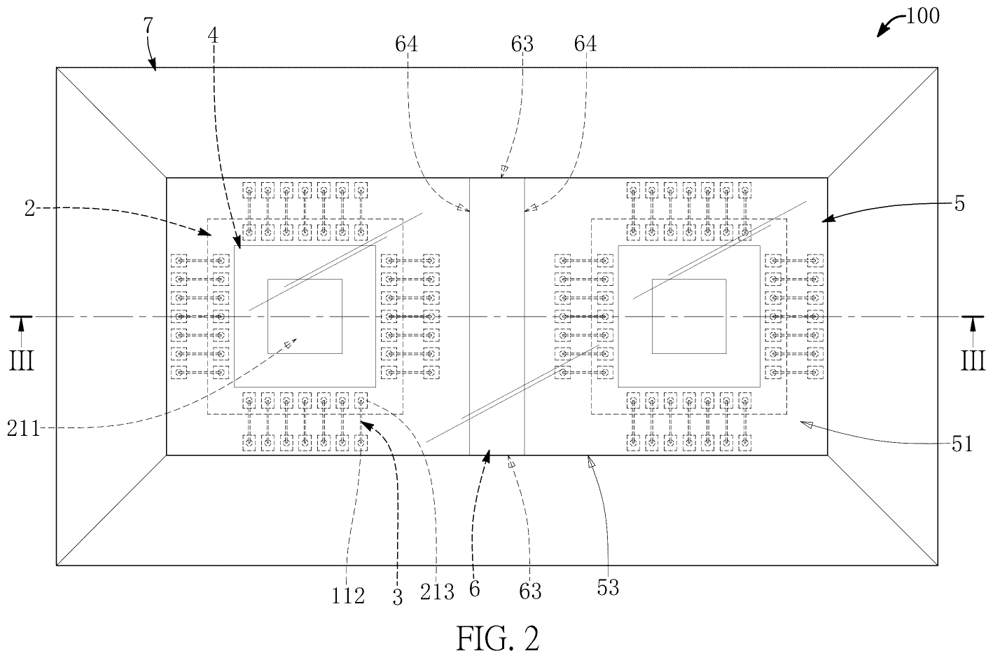

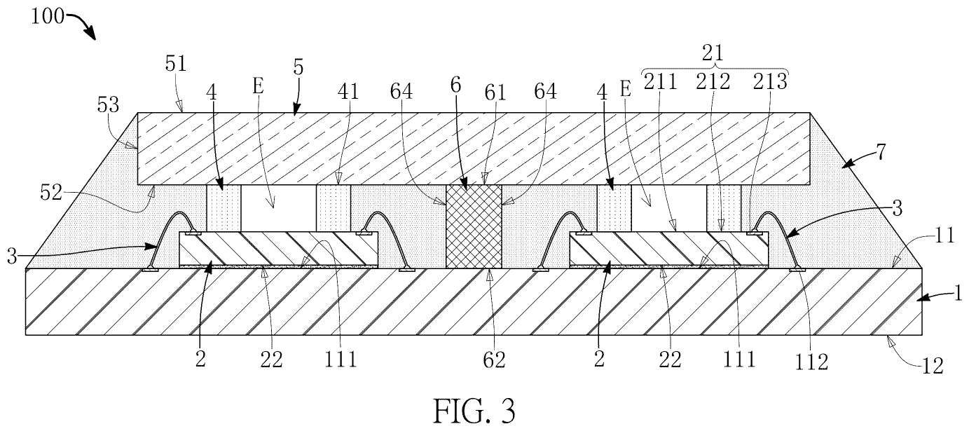

Referring to FIG. 1 to FIG. 6, a first embodiment of the present disclosure is provided. As shown in FIG. 1 to FIG. 4, the present embodiment provides a sensor package structure 100, which includes a substrate 1, two sensor chips 2 disposed on the substrate 1, a plurality of metal wires 3 electrically coupled to the two sensor chips 2 and the substrate 1, two ring-shaped supporting layers 4 respectively disposed on the two sensor chips 2, a light-permeable layer 5 disposed on the two ring-shaped supporting layers 4, a light block barrier 6 fixed to the light-permeable layer 5, and an encapsulant 7 that is formed on the substrate 1. In other words, any package structure not encapsulating multiple sensor chips therein has a structural design different from that of the sensor package structure 100 provided by the present embodiment.

It should be noted that the sensor package structure 100 in the present embodiment includes the above components, but can be adjusted or changed according to design requirements. For example, in other embodiments of the present disclosure not shown in the drawings, the sensor package structure 100 can be provided without the metal wires 3, and each of the two sensor chips 2 is fixed onto and electrically coupled to the substrate 1 in a flip-chip manner or an adhering manner. The structure and connection relationship of each component of the sensor package structure 100 will be recited in the following description.

The substrate 1 of the present embodiment has a square shape or a rectangular shape, but the present disclosure is not limited thereto. An upper surface 11 of the substrate 1 includes two chip-bonding regions 111, and the substrate 1 includes a plurality of bonding pads 112 that are disposed on the upper surface 11 and are arranged outside of the two chip-bonding regions 111. Each of the two chip-bonding regions 111 in the present embodiment is surrounded by the bonding pads 112 that are in a ring-shaped arrangement, but the present disclosure is not limited thereto. For example, in other embodiments of the present disclosure not shown in the drawings, each of the two chip-bonding regions 111 can be provided with the bonding pads 112 arranged in two rows respectively at two opposite sides thereof.

In addition, the substrate 1 can be further provided with a plurality of soldering balls (not shown in the drawings) disposed on a lower surface 12 thereof. The substrate 1 can be soldered onto an electronic component (not shown in the drawings) through the soldering balls, thereby electrically connecting the sensor package structure 100 to the electronic component.

Each of the two sensor chips 2 in the present embodiment has a square shape or a rectangular shape and is a time of flight (TOF) sensor chip, and the two sensor chips 2 are of substantially a same structure, but the present disclosure is not limited thereto. For example, in other embodiments of the present disclosure, the two sensor chips 2 can be of different structures according to practical requirements.

In the present embodiment, bottom surfaces 22 of the two sensor chips 2 are respectively fixed onto the two chip-bonding regions 111 of the substrate 1 (through chip-bonding adhesives). A top surface 21 of each of the two sensor chips 2 has a sensing region 211 and a carrying region 212 that has a ring shape arranged around the sensing region 211. Two ends of each of the metal wires 3 are respectively connected to the substrate 1 and the top surface 21 (e.g., the carrying region 212) of one of the two sensor chips 2, so that the substrate 1 is electrically coupled to each of the two sensor chips 2.

Specifically, each of the two sensor chips 2 includes a plurality of connection pads 213 arranged on the carrying region 212. In other words, the connection pads 213 are arranged outside of the sensing region 211. The number and positions of the connection pads 213 of the two sensor chips 2 in the present embodiment correspond to those of the bonding pads 112 of the substrate 1. In other words, the connection pads 213 of each of the two sensor chips 2 in the present embodiment are substantially in a ring-shaped arrangement. Moreover, the two ends of each of the metal wires 3 are respectively connected to one of the bonding pads 112 and the corresponding connection pad 213.

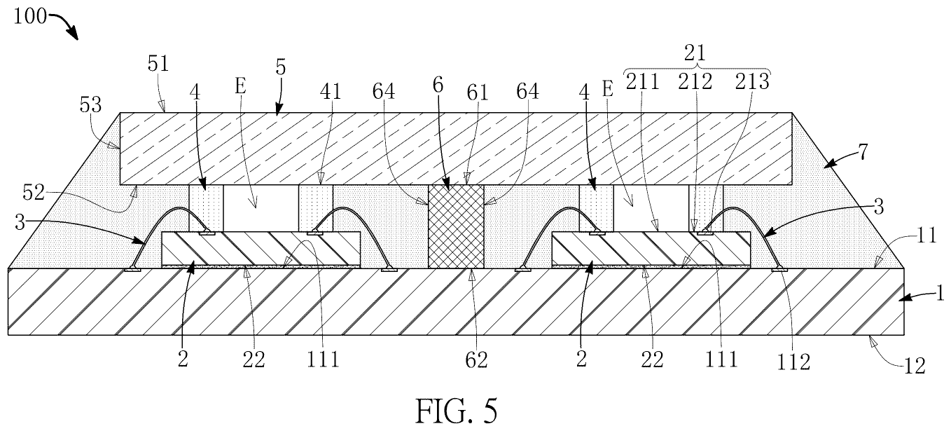

The two ring-shaped supporting layers 4 are respectively disposed on the carrying regions 212 of the two sensor chips 2 and respectively surround the sensing regions 211 of the two sensor chips 2. In the present embodiment, the two ring-shaped supporting layers 4 are located inside of the metal wires 3 and are not in contact with any one of the metal wires 3 (e.g., each of the metal wires 3 is arranged outside of one of the two ring-shaped supporting layers 4 and is entirely embedded in the encapsulant 7), but the present disclosure is not limited thereto. For example, as shown in FIG. 5, a part of each of the metal wires 3 is embedded in one of the two ring-shaped supporting layers 4, and a remaining part of each of the metal wires 3 is embedded in the encapsulant 7.

Specifically, as shown in FIG. 1 to FIG. 4, the two ring-shaped supporting layers 4 in the present embodiment are of substantially a same structure, and each of the two ring-shaped supporting layers 4 has a rectangular ring-shape or a square ring-shape, but the present disclosure is not limited thereto. For example, in other embodiments of the present disclosure not shown in the drawings, the two ring-shaped supporting layers 4 can be of different structures according to practical requirements; or, each of the two ring-shaped supporting layers 4 can be opaque, translucent, or transparent according to practical requirements.

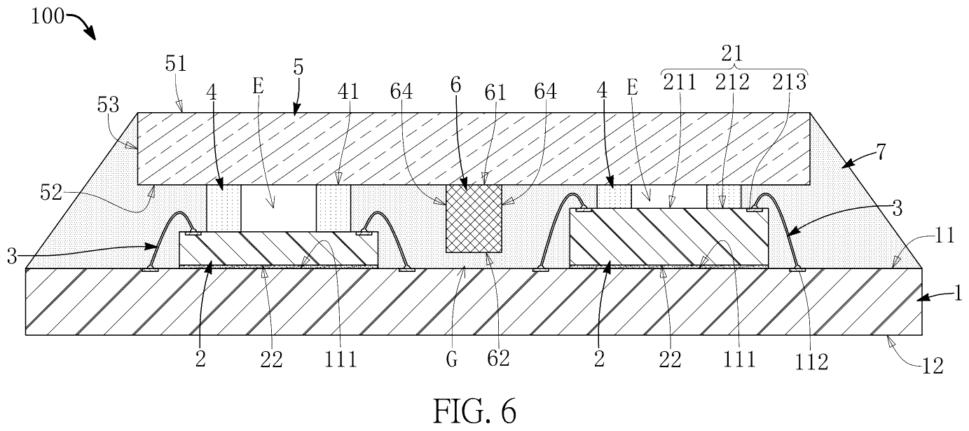

In addition, top sides 41 of the two ring-shaped supporting layers 4 are preferably coplanar with each other. In other words, a sum of heights of any one of the two ring-shaped supporting layers 4 and a corresponding one of the two sensor chips 2 is equal to a sum of heights of another one of the two ring-shaped supporting layers 4 and a corresponding one of the two sensor chips 2. Accordingly, as shown in FIG. 6, when the two sensor chips 2 have different heights, the sensor chip 2 having a smaller height is cooperated with one of the two ring-shaped supporting layers 4 having a larger height, and the sensor chip 2 having a larger height is cooperated with another one of the two ring-shaped supporting layers 4 having a smaller height, thereby maintaining the top sides of the two ring-shaped supporting layers 4 to be substantially coplanar with each other.

As shown in FIG. 1 to FIG. 4, the light-permeable layer 5 in the present embodiment is a transparent and flat glass board, but the present disclosure is not limited thereto. The light-permeable layer 5 has an inner surface 52, an outer surface 51 being opposite to the inner surface 52, and a surrounding lateral surface 53 that is connected to the inner surface 52 and the outer surface 51. The light-permeable layer 5 is disposed on the top sides 41 of the two ring-shaped supporting layers 4 through the inner surface 52, so that the inner surface 52 of the light-permeable layer 5, each of the two ring-shaped supporting layers 4, and the corresponding sensor chip 2 jointly define an enclosed space E that is filled with air.

The light block barrier 6 is opaque, the light block barrier 6 is arranged between the two sensor chips 2 and is also arranged between the two ring-shaped supporting layers 4, and the metal wires 3 are not in contact with the light block barrier 6. A top side 61 of the light block barrier 6 is fixed onto the inner surface 52 of the light-permeable layer 5. In other words, the top side 61 of the light block barrier 6 is coplanar with the top sides 41 of the two ring-shaped supporting layers 4. Accordingly, any barrier that is not fixed onto a light-permeable layer is different from the light block barrier 6 provided by the present embodiment.

Moreover, the light block barrier 6 has two lateral surfaces 64 respectively facing toward the two ring-shaped supporting layers 4, two end sides 63 being flush with the surrounding lateral surface 53 of the light-permeable layer 5, and a bottom side 62 that faces toward the substrate 1. The bottom side 62 of the light block barrier 6 is arranged between the two sensor chips 2 and is not fixed to the substrate 1. In the present embodiment, the substrate 1 and the bottom side 62 of the light block barrier 6 have a gap G therebetween, and the gap G is less than or equal to 10% of a thickness of any one of the two sensor chips 2.

The encapsulant 7 of the present embodiment is opaque for blocking visible light from passing therethrough. The encapsulant 7 is a solidified liquid encapsulant and is formed on the upper surface 11 of the substrate 1, and edges of the encapsulant 7 are flush with edges of the substrate 1. The two sensor chips 2, the two ring-shaped supporting layers 4, the light-permeable layer 5, the light block barrier 6, and at least part of each of the metal wires 3 are embedded in the encapsulant 7, and at least part of the outer surface 51 of the light-permeable layer 5 is exposed from the encapsulant 7, but the present disclosure is not limited thereto.

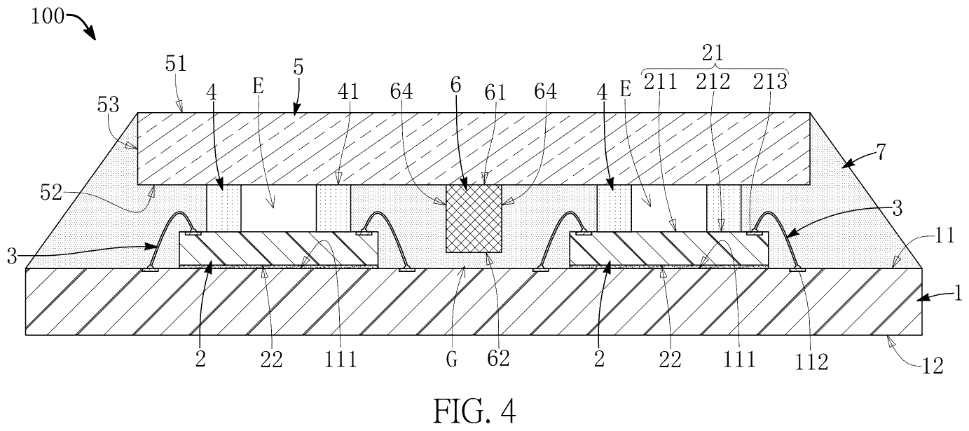

Specifically, the bottom side 62, the two end sides 63, and the two lateral surfaces 64 of the light block barrier 6 are embedded in the encapsulant 7. Moreover, the gap G shown in FIG. 4 is fully filled by the encapsulant 7.

In summary, the light-permeable layer 5 of the sensor package structure 100 in the present embodiment is provided with the light block barrier 6 fixed thereon for separating the two sensor chips 2 from each other, thereby effectively preventing the two sensor chips 2 from affecting each other.

### Second Embodiment

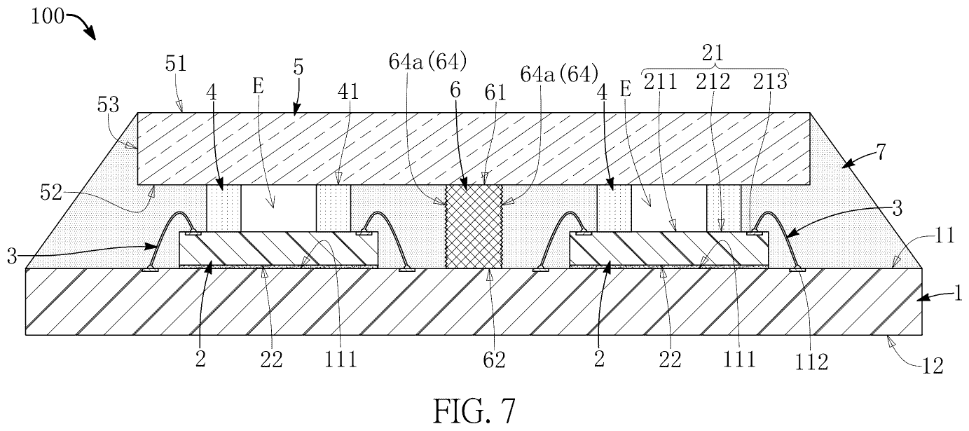

Referring to FIG. 7, a second embodiment of the present disclosure, which is similar to the first embodiment of the present disclosure, is provided. For the sake of brevity, descriptions of the same components in the first and second embodiments of the present disclosure will be omitted herein, and the following description only discloses different features between the first and second embodiments.

In the present embodiment, the light block barrier 6 has two roughened lateral surfaces 64a that respectively face toward the two ring-shaped supporting layers 4 and that are embedded in the encapsulant 7.

### Third Embodiment

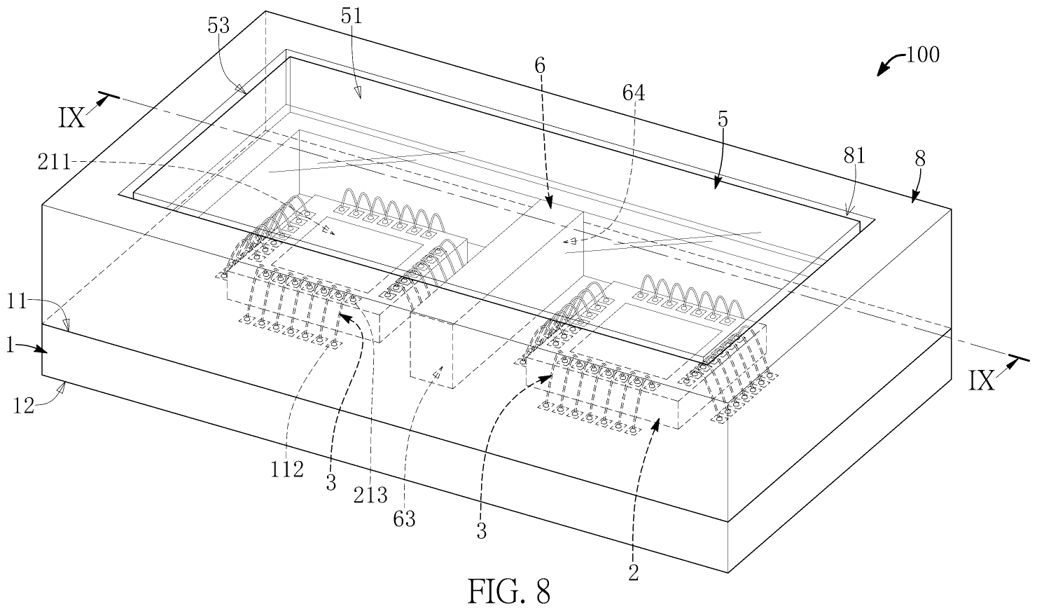

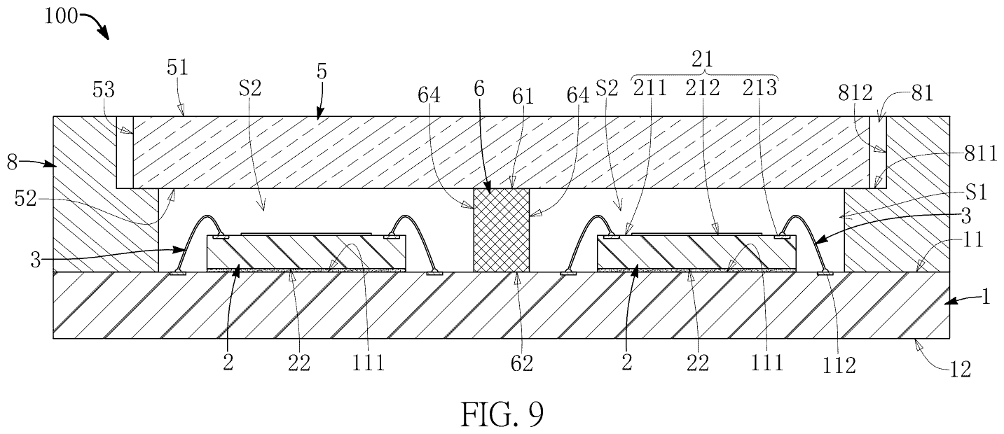

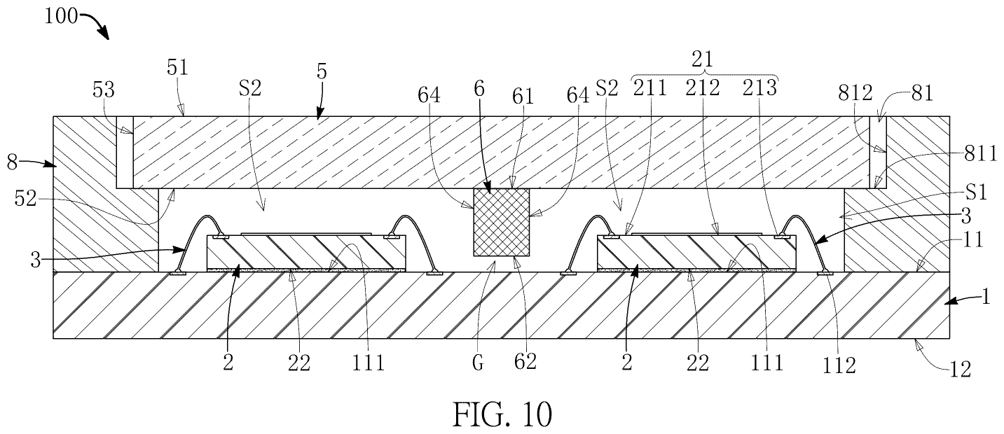

Referring to FIG. 8 to FIG. 11, a third embodiment of the present disclosure, which is similar to the first embodiment of the present disclosure, is provided. For the sake of brevity, descriptions of the same components in the first and third embodiments of the present disclosure will be omitted herein, and the following description only discloses different features between the first and third embodiments.

In the present embodiment, the sensor package structure 100 includes a substrate 1, two sensor chips 2 disposed on the substrate 1, a plurality of metal wires 3 electrically coupled to the two sensor chips 2 and the substrate 1, a ring-shaped frame 8 formed on the substrate 1 and surrounding the two sensor chips 2 and the metal wires 3, a light-permeable layer 5 disposed on the ring-shaped frame 8, a light block barrier 6 that is fixed to the light-permeable layer 5.

It should be noted that sensor package structure 100 in the present embodiment includes the above components, but can be adjusted or changed according to design requirements. For example, in other embodiments of the present disclosure not shown in the drawings, the sensor package structure 100 can be provided without the metal wires 3, and each of the two sensor chips 2 is fixed onto and electrically coupled to the substrate 1 in a flip-chip manner or an adhering manner. Moreover, the substrate 1, the two sensor chips 2, and the metal wires 3 of the present embodiment are substantially identical to those of the first embodiment, and are not described in the following description for the sake of brevity.

The ring-shaped frame 8 and the substrate 1 jointly define a chip receiving slot S1, and the two sensor chips 2 and the metal wires 3 are arranged in the chip receiving slot S1. Moreover, the ring-shaped frame 8 has a ring-shaped notch 81 recessed in an inner side thereof, and the ring-shaped notch 81 has a tread surface 811 and a riser surface 812 that is connected to the tread surface 811.

The light-permeable layer 5 in the present embodiment is a transparent and flat glass board, but the present disclosure is not limited thereto. The light-permeable layer 5 has an inner surface 52, an outer surface 51 being opposite to inner surface 51, and a surrounding lateral surface 53 that is connected to the inner surface 52 and the outer surface 51. The inner surface 52 of the light-permeable layer 5 is disposed on the ring-shaped frame 8 so as to enclose the chip receiving slot S1 and an inner space of the chip receiving slot S1.

Furthermore, a peripheral portion of the light-permeable layer 5 is disposed in the ring-shaped notch 81, and the light-permeable layer 5 does not protrude from a top side of the ring-shaped frame 8. In the present embodiment, the inner surface 52 of the light-permeable layer 5 is disposed on the tread surface 811, and the surrounding lateral surface 53 of the light-permeable layer 5 is not in contact with the riser surface 812, but the present disclosure is not limited thereto.

The light block barrier 6 is opaque, the light block barrier 6 is arranged between the two sensor chips 2, and the metal wires 3 are not in contact with the ring-shaped frame 8 and the light block barrier 6. A top side 61 of the light block barrier 6 is fixed onto the inner surface 52 of the light-permeable layer 5. In other words, the top side 61 of the light block barrier 6 is coplanar with the tread surface 811 of the ring-shaped frame 8.

Moreover, the light block barrier 6 has two lateral surfaces 64 respectively facing toward the two sensor chips 2, two end sides 63 being flush with the surrounding lateral surface 53 of the light-permeable layer 5, and a bottom side 62 that faces toward the substrate 1. The bottom side 62 of the light block barrier 6 is arranged between the two sensor chips 2 and is not fixed to the substrate 1.

In the present embodiment, the substrate 1 and the bottom side 62 of the light block barrier 6 have a gap G therebetween, and the gap G is less than or equal to 10% of a thickness of any one of the two sensor chips 2. Specifically, the chip receiving slot S1 is divided into two accommodating spaces S2 through the light block barrier 6, the two accommodating spaces S2 are in spatial communication with each other through the gap G, and the two sensor chips 2 are respectively arranged in the two accommodating spaces S2.

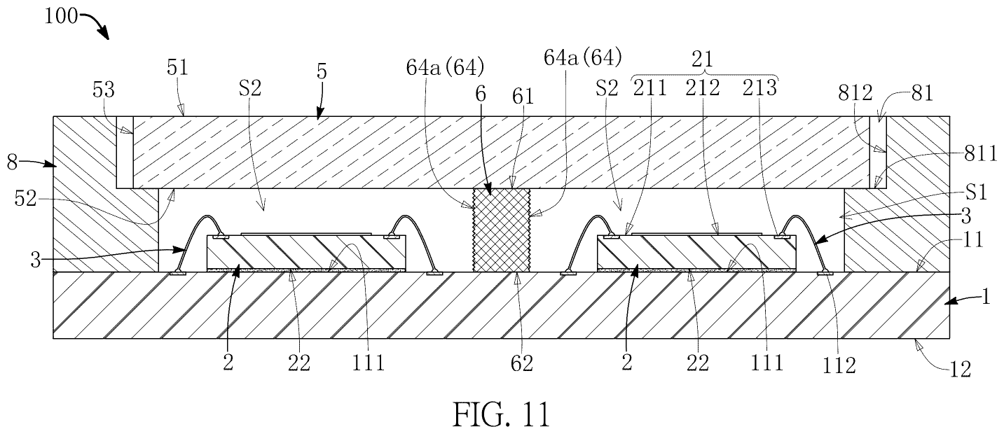

In addition, the two lateral surfaces 64 of the light block barrier 6 can be formed as two roughened lateral surfaces 64 (as shown in FIG. 11) according to practical requirements, thereby enabling the two roughened lateral surfaces 64 to scatter light irradiated thereon for effectively preventing the two sensor chips 2 from affecting each other.

### Beneficial Effects of the Embodiments

In conclusion, the light-permeable layer of the sensor package structure in the present disclosure is provided with the light block barrier fixed thereon for separating the two sensor chips from each other, thereby effectively preventing the two sensor chips from affecting each other.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A sensor package structure, comprising:
a substrate;
two sensor chips disposed on and electrically coupled to the substrate, wherein a top surface of each of the two sensor chips includes a sensing region and a carrying region that surrounds the sensing region;
two ring-shaped supporting layers respectively disposed on the carrying regions of the two sensor chips and respectively surrounding the sensing regions of the two sensor chips;
a light-permeable layer having an inner surface, an outer surface, and a surrounding lateral surface that is connected to the inner surface and the outer surface, wherein the inner surface of the light-permeable layer is disposed on top sides of the two ring-shaped supporting layers, and each of the two ring-shaped supporting layers, the light-permeable layer, and the top surface of a corresponding one of the two sensor chips jointly define an enclosed space;
a light block barrier having a top side that is fixed onto the inner surface of the light-permeable layer and that is coplanar with the top sides of the two ring-shaped supporting layers, wherein the light block barrier is arranged between the two sensor chips; and
an encapsulant formed on the substrate, wherein the two sensor chips, the two ring-shaped supporting layers, the light block barrier, and the light-permeable layer are embedded in the encapsulant, and the outer surface of the light-permeable layer is at least partially exposed from the encapsulant.

2. The sensor package structure according to claim 1, wherein a bottom side of the light block barrier is not fixed to the substrate.

3. The sensor package structure according to claim 2, wherein the substrate and the bottom side of the light block barrier have a gap therebetween, and the gap is less than or equal to 10% of a thickness of any one of the two sensor chips.

4. The sensor package structure according to claim 1, wherein the light block barrier has two lateral surfaces that respectively face toward the two ring-shaped supporting layers and that are embedded in the encapsulant.

5. The sensor package structure according to claim 1, wherein the light block barrier has two roughened lateral surfaces that respectively face toward the two ring-shaped supporting layers.

6. The sensor package structure according to claim 1, wherein the light block barrier has two end sides that are flush with the surrounding lateral surface of the light-permeable layer.

7. The sensor package structure according to claim 1, further comprising a plurality of metal wires each having a first end and a second end, wherein the metal wires are not in contact with the light block barrier, the first ends of the metal wires are connected to the substrate, and the second ends of the metal wires are connected to the top surfaces of the two sensor chips.

8. The sensor package structure according to claim 7, wherein the metal wires are embedded in the encapsulant.

9. The sensor package structure according to claim 7, wherein at least one of the metal wires is embedded in the encapsulant and one of the two ring-shaped supporting layers.

10. The sensor package structure according to claim 1, wherein a sum of heights of any one of the two ring-shaped supporting layers and a corresponding one of the two sensor chips is equal to a sum of heights of another one of the two ring-shaped supporting layers and a corresponding one of the two sensor chips.

11. A sensor package structure, comprising:
a substrate;
a ring-shaped frame formed on the substrate to jointly define a chip receiving slot;
two sensor chips disposed on and electrically coupled to the substrate, wherein the two sensor chips are arranged in the chip receiving slot;
a light-permeable layer having an inner surface, an outer surface, and a surrounding lateral surface that is connected to the inner surface and the outer surface, wherein the inner surface of the light-permeable layer is disposed on the ring-shaped frame so as to enclose the chip receiving slot and an inner space of the chip receiving slot; and
a light block barrier having a top side that is fixed onto the inner surface of the light-permeable layer, wherein the light block barrier is arranged in the chip receiving slot and is arranged between the two sensor chips.

12. The sensor package structure according to claim 11, wherein a bottom side of the light block barrier is not fixed to the substrate.

13. The sensor package structure according to claim 12, wherein the substrate and the bottom side of the light block barrier have a gap therebetween, and the gap is less than or equal to 10% of a thickness of any one of the two sensor chips.

14. The sensor package structure according to claim 11, wherein the light block barrier has two roughened lateral surfaces that respectively face toward the two ring-shaped supporting layers.

15. The sensor package structure according to claim 11, wherein the light block barrier has two end sides that are flush with the surrounding lateral surface of the light-permeable layer, the chip receiving slot is divided into two accommodating spaces through the light block barrier, and the two sensor chips are respectively arranged in the two accommodating spaces.

16. The sensor package structure according to claim 15, wherein the substrate and the bottom side of the light block barrier have a gap therebetween, and the two accommodating spaces are in spatial communication with each other through the gap.

17. The sensor package structure according to claim 11, further comprising a plurality of metal wires each having a first end and a second end, wherein the metal wires are not in contact with the light block barrier and the ring-shaped frame, the first ends of the metal wires are connected to the substrate, and the second ends of the metal wires are connected to the top surfaces of the two sensor chips.

18. The sensor package structure according to claim 11, wherein the ring-shaped frame has a ring-shaped notch recessed in an inner side thereof, and a peripheral portion of the light-permeable layer is disposed in the ring-shaped notch.

19. The sensor package structure according to claim 18, wherein the ring-shaped notch has a tread surface and a riser surface that is connected to the tread surface, the inner surface of the light-permeable layer is disposed on the tread surface, and the surrounding lateral surface of the light-permeable layer is not in contact with the riser surface.

20. The sensor package structure according to claim 18, wherein the light-permeable layer does not protrude from a top side of the ring-shaped frame.
